(19) United States
(12) Patent Application Publication
(10) Pub. No.: US 2013/0187526 A1
(43) Pub. Date: Jul. 25, 2013

(54) DETACHABLE CAGE AND APPARATUS CASING THEREWITH

(71) Applicant: You-Hsiung Lu, New Taipei City (TW)

(72) Inventor: You-Hsiung Lu, New Taipei City (TW)

(21) Appl. No.: 13/448,375

(22) Filed: Apr. 16, 2012

(30) Foreign Application Priority Data
Jan. 19, 2012 (TW) 101102188

(51) Int. Cl. H05K 7/14; H05K 5/02

(52) U.S. Cl. 312/333; 211/26.2

(57) ABSTRACT

A detachable cage and an apparatus casing are disclosed. The apparatus casing includes a casing body, a first engagement structure and a second engagement structure disposed on the casing body, and the detachable cage. The detachable cage includes a cage body, a third engagement structure, a fourth engagement structure, and a fastening mechanism disposed on the cage body. The detachable cage is installed on the casing body by engaging the third engagement structure and the fourth engagement structure with the first engagement structure and the second engagement structure respectively; therein, the fastening mechanism is used for fastening the detachable cage on the casing body by use of a screw part screwing into a threaded hole of the casing body. Therefore, the invention provide a user a simple manipulation of installing the detachable cage onto the apparatus casing or detaching the detachable cage from the apparatus casing.

### BACKGROUND OF THE INVENTION

1. Field of the Invention

The invention relates to a detachable cage and an apparatus casing, and especially relates to a detachable cage capable of being installed or detached and an apparatus casing having the detachable cage.

2. Description of the Prior Art

Common electronic equipment such as computer host is equipped with a plurality of replaceable electronic devices such as hard disks. In general, a apparatus casing for the computer host is equipped with a detachable cage for convenience of taking out, adding, or replacing the hard disks disposed therein, so that it is convenient for a user to fix the hard disks on the detachable cage outside the apparatus casing in advance, without the limitation by usable operation space provided inside the apparatus casing. Then, the user fixes the detachable cage together with the hard disks in the apparatus casing. The installation of the hard disked into the apparatus casing is therefore completed. In order to prevent the detachable cage from vibrating in the apparatus casing, the detachable cage is usually fixed by several screws. However, common screws need a screw driver to be screwed tight or loose, which adds inconvenience to the installation and detachment of the detachable cage. Furthermore, screwing the screws tight or loose considerably takes time, which makes the whole installation and detachment time-waste. Therefore, the installation and detachment for the current detachable cage is tedious and annoying, which is quite inconvenient.

### SUMMARY OF THE INVENTION

Therefore, a detachable cage according to one embodiment of the invention is provided. The detachable cage is capable of being installed in an apparatus casing in a detachable way. The apparatus casing includes a first engagement structure, a second engagement structure, and a threaded hole. The detachable cage includes a cage body, a third engagement structure, a fourth engagement structure, and a fastening mechanism. The cage body is capable of fixing at least one electronic device thereon. The cage body has a first side and a second side opposite to the first side. The third engagement structure is disposed on the first side of the cage body and capable of being movably engaged with the first engagement structure in a sliding direction. The fourth engagement structure is disposed on the second side of the cage body and capable of being movably engaged with the second engagement structure in the sliding direction. The fastening mechanism is disposed on the cage body and includes a screw part. After the third engagement structure and the fourth engagement structure are engaged with the first engagement structure and the second engagement structure respectively, the screw part is capable of being screwed into the threaded hole so as to fix the detachable cage in the apparatus casing.

Furthermore, an apparatus casing according to one embodiment of the invention is provided. The apparatus casing includes a casing body, a first engagement structure, a second engagement structure, and a detachable cage. The casing body includes a threaded hole. The first engagement structure and the second engagement structure are disposed on the casing body. The detachable cage includes a cage body, a third engagement structure, a fourth engagement structure, and a fastening mechanism. The cage body is capable of fixing at least one electronic device thereon. The cage body includes a first side and a second side opposite to the first side. The third engagement structure is disposed on the first side of the cage body and is capable of being movably engaged with the first engagement structure in a sliding direction. The fourth engagement structure is disposed on the second side of the cage body and is capable of being movably engaged with the second engagement structure in the sliding direction. The fastening mechanism is disposed on the cage body and includes a screw part. After the third engagement structure and the fourth engagement structure are engaged with the first engagement structure and the second engagement structure respectively, the screw part is capable of being screwed into the threaded hole so as to fix the detachable cage on the casing body.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded view of an apparatus casing according to an embodiment of the invention.

FIG. 2 is a schematic diagram illustrating the detachable cage being slid to be engaged to the casing body of the apparatus casing in FIG. 1.

FIG. 3 is a schematic diagram illustrating the detachable cage having been engaged to the casing body of the apparatus casing in FIG. 1.

FIG. 4 is a schematic diagram illustrating a detachable cage and a casing body of an apparatus casing having been engaged according to another embodiment.

### DETAILED DESCRIPTION

The invention is to provide a detachable cage capable of being installed in an apparatus casing in a detachable way. The apparatus casing includes a first engagement structure, a second engagement structure, and a threaded hole. The detachable cage includes a cage body, a third engagement structure, a fourth engagement structure, and a fastening mechanism. The cage body is capable of fixing at least one electronic device thereon. The cage body has a first side and a second side opposite to the first side. The third engagement structure is disposed on the first side of the cage body and capable of being movably engaged with the first engagement structure in a sliding direction. The fourth engagement structure is disposed on the second side of the cage body and capable of being movably engaged with the second engagement structure in the sliding direction. The fastening mechanism is disposed on the cage body and includes a screw part. After the third engagement structure and the fourth engagement structure are engaged with the first engagement structure and the second engagement structure respectively, the screw part is capable of being screwed into the threaded hole so as to fix the detachable cage in the apparatus casing.

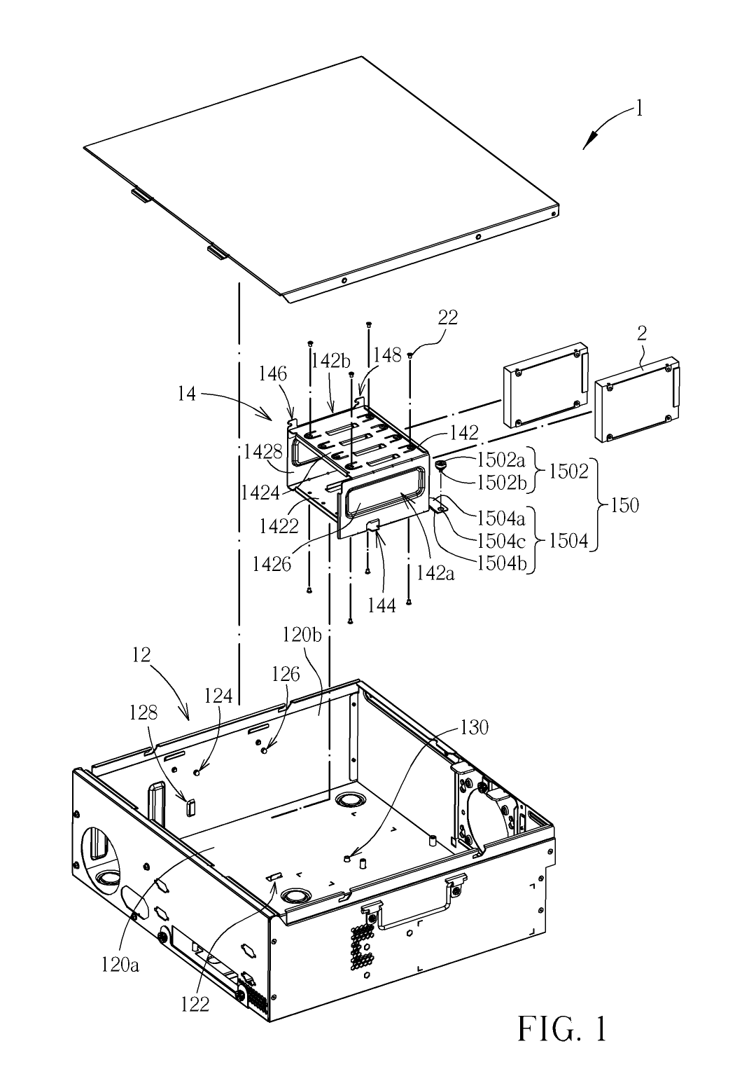

Please refer to FIG. 1, which is an exploded view of an apparatus casing 1 according to an embodiment of the invention. In the embodiment, the apparatus casing 1 can be a computer casing, but the invention is not limited thereto. The apparatus casing 1 includes a casing body 12 and a detachable cage 14. The detachable cage 14 is installed on the casing body 12 in a detachable way. The detachable way will be described in detail later.

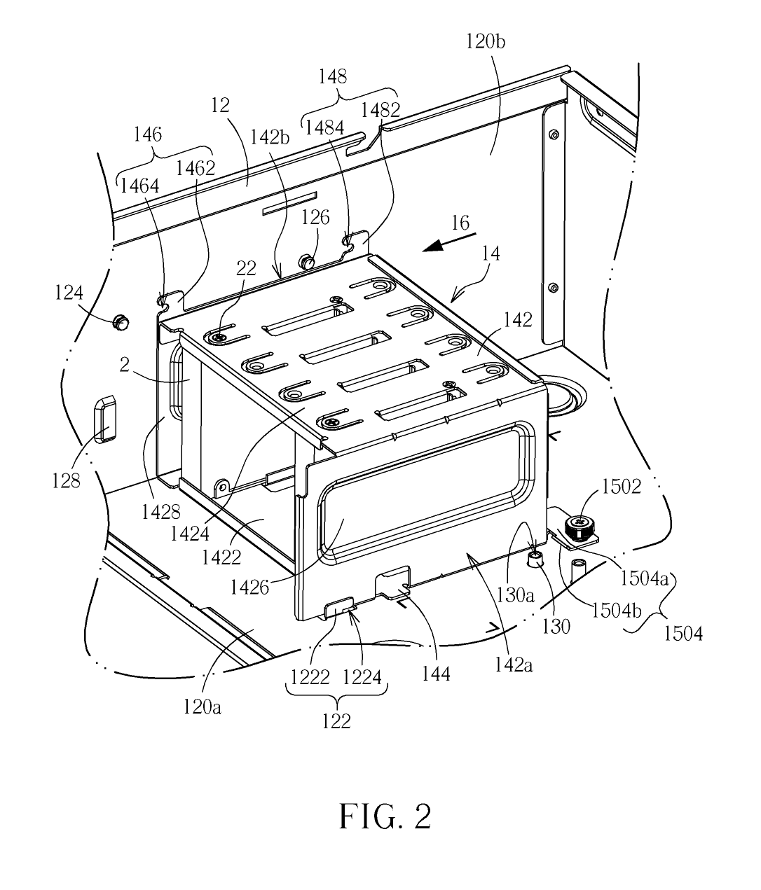

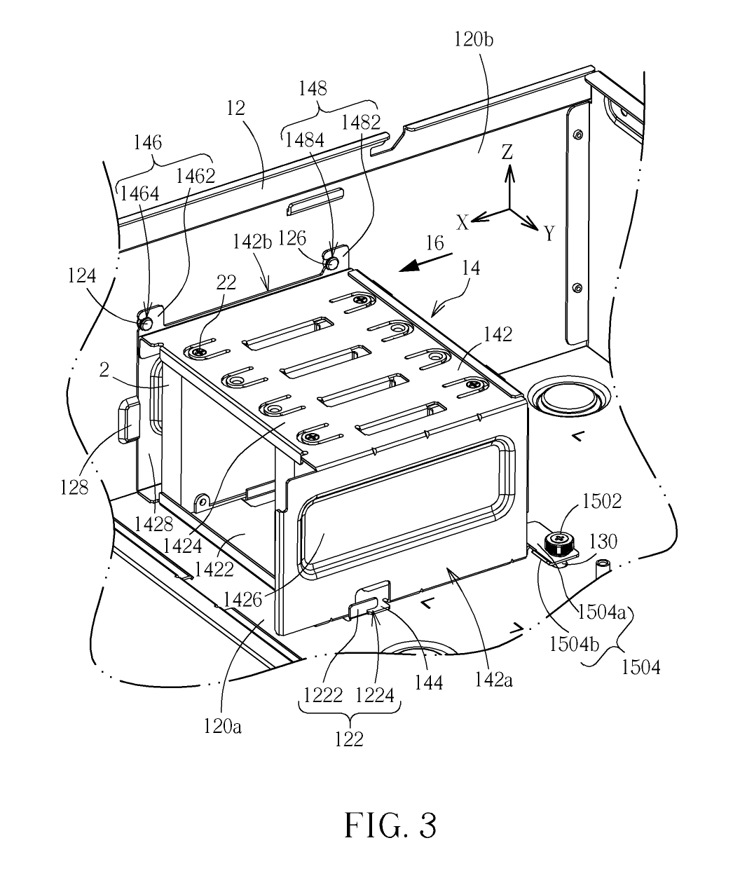

Please refer FIG. 2 and FIG. 3. FIG. 2 is a schematic diagram illustrating the detachable cage 14 being slid to be engaged to the casing body 12. FIG. 3 is a schematic diagram illustrating the detachable cage 14 having been engaged to the casing body 12. The apparatus casing 1 includes a first engagement structure 122, a second engagement structure 124, a fifth engagement structure 126, and a blocking structure 128. The casing body 12 has a bottom portion 120a and a sidewall 120b. The first engagement structure 122 is disposed on the bottom portion 120a. The second engagement structure 124, the fifth engagement structure 126, and the blocking structure 128 are disposed on the sidewall 120b. The casing body 12 includes a protrusion boss 130 disposed on the bottom portion 120a. A threaded hole 130a is formed on the protrusion boss 130. The detachable cage 14 includes a cage body 142, a third engagement structure 144, a fourth engagement structure 146, a sixth engagement structure 148, and a fastening mechanism 150. The cage body 142 includes a bottom plate 1422, a top plate 1424, and two side plates 1426 and 1428. The cage body 142 includes a first side 142a and a second side 142b opposite to the first side 142a. The cage body 142 is capable of fixing a plurality of electronic devices 2 such as hard disks thereon by use of screws 22. The third engagement structure 144 is disposed on the first side 142a of the cage body 142. The fourth engagement structure 146 and the sixth engagement structure 148 are disposed on the second side 142b of the cage body 142. The fastening mechanism 150 is disposed on the cage body 142 and includes a screw part 1502. The third engagement structure 144, the fourth engagement structure 146, and the sixth engagement structure 148 are capable of being slid to be engaged with the first engagement structure 122, the second engagement structure 124, and the fifth engagement structure 126 respectively in a sliding direction 16. When the third engagement structure 144, the fourth engagement structure 146, and the sixth engagement structure 148 are engaged with the first engagement structure 122, the second engagement structure 124, and the fifth engagement structure 126 respectively, the blocking structure 128 blocks an edge of the side plate 1428 of the cage body 142. The screw part 1502 is capable of being screwed into the threaded hole 130a so as to fix the detachable cage 14 on the casing body 12.

In further details, the first engagement structure 122 includes a fixed plate 1222 fixed on the bottom portion 120a of the casing body 12. The fixed plate 1222 thereon forms a slide slot 1224. The bottom portion 120a is bent to extend to form the fixed plate 1222, of which the profile is substantially L-shaped. The slide slot 1224 is formed between the fixed plate 1222 and the bottom portion 120a. The third engagement structure 144 is a sliding plate. The bottom plate 1422 extends out the side plate 1426 to form the sliding plate. The third engagement structure 144 is engaged with the first engagement structure 122 by the sliding plate sliding into the slide slot 1224 and being blocked by the slide slot 1224; therein, the sliding plate slides on the bottom portion 120a of the casing body 12 in the sliding direction 16. The second engagement structure 124 and the fifth engagement structure 126 respectively are a guiding boss fixed on the sidewall 120b of the casing body 12. The fourth engagement structure 146 and the sixth engagement structure 148 include two sliding plates 1462 and 1482 respectively, fixed on the second side 142b of the cage body 142. The side plate 1428 extends out the top plate 1424 to form the sliding plates 1462 and 1482. The sliding plates 1462 and 1464 thereon form two slide slots 1464 and 1484 respectively. The fourth engagement structure 146 and the sixth engagement structure 148 are engaged with the second engagement structure 124 and the fifth engagement structure 126 by the guiding bosses relatively sliding in the slide slots 1464 and 1484 respectively and blocking the slide slots 1464 and 1484; therein, the sliding plates 1462 and 1464 slide on the sidewall 120b of the casing body 12 in the sliding direction 16. In the embodiment, the guiding boss is a T-shaped guiding boss, which includes a bigger head and a leading structure at its neck portion, so as to prevent the sliding plates 1462 and 1464 from sliding out of the guiding bosses and to guide the sliding plates 1462 and 1464 to the guiding bosses. Therefore, the sliding plates 1462 and 1464 slide between the T-shaped guiding bosses and the sidewall 120b during engaging of the fourth engagement structure 146 and the sixth engagement structure 148 with the second engagement structure 124 and the fifth engagement structure 126 respectively.

The fastening mechanism 150 includes a plate member 1504 fixed on the cage body 142. The plate member 1504 includes a fixed portion 1504a and a guiding portion 1504b bent to extend from the fixed portion 1504a in the sliding direction 16. A through hole 1504c is formed on the fixed portion 1504a. The screw part 1502 includes a threaded portion 1502a and a screwing manipulation portion 1502b connected to the threaded portion 1502a. The screwing manipulation portion 1502b is provided with embossing on its circumference for user to screw by hand. During engaging of the third engagement structure 144, the fourth engagement structure 146, and the sixth engagement structure 148 with the first engagement structure 122, the second engagement structure 124, and the fifth engagement structure 126 respectively, the guiding portion 1504b is capable of guiding the fixed portion 1504a to slide onto the protrusion boss 130 such that the through hole 1504c is capable of being aligned with the threaded hole 130a. When the third engagement structure 144, the fourth engagement structure 146, and the sixth engagement structure 148 are engaged with the first engagement structure 122, the second engagement structure 124, and the fifth engagement structure 126 respectively, the through hole 1504c is aligned with the threaded hole 130a, so that the threaded portion 1502a of the screw part 1502 is capable of passing through the through hole 1504c to be screwed into the threaded hole 130a so as to fix the plate member 1504 (or the fixed portion 1504a) on the protrusion boss 130. The detachable cage 14 is therefore fixed on the casing body 12.

In the embodiment, the first engagement structure 122 has a function of Z-direction constraint on the third engagement structure 144. The second engagement structure 124 and the fifth engagement structure 126 have a function of Y and Z-directions constraint on the fourth engagement structure 146 and the sixth engagement structure 148. The bottom portion 120a of the casing body 12 has a function of minus Z-direction constraint on the cage body 142. The sidewall 120b of the casing body 12 has a function of minus Y-direction constraint on the cage body 142. Therefore, the detachable cage 14 is capable of being engaged with the casing body 12 stably in the sliding direction 16. Furthermore, in the embodiment, the contact areas between the engagement structures 122, 124, 126, 144, 146 and 148 are not large, so the engagement structures 122, 124, 126, 144, 146 and 148 may be damaged if a user slides the detachable cage 14 with a larger force. Hence, the apparatus casing 1 is provided with the blocking structure 128 to block the edge of the side plate 1428 of the cage body 142, so as to increase the contact area of the detachable cage 14 in the sliding direction 16 for eliminating or reducing the above potential damage. In addition, in the embodiment, the fastening mechanism 150 is disposed substantially on the first side 142a of the cage body 142, so the sides 142a and 142b of the cage body 142 contact the casing body 12 so that the detachable cage 14 is fixed on the casing body 12 stably.

Besides, in the embodiment, the casing body 12 and the cage body 142 may be formed by pressing plate members, the engagement structures 122, 144, 146 and 148 may be formed by bending plate members, and the blocking structure 128 may be formed by protruding the sidewall 120b of the casing body 12 by pressing; however, the invention is not limited thereto. Furthermore, in practice, for any pair of corresponding engagement structures such as the first engagement structure 122 corresponding to the third engagement structure 144, the physical structure can be swapped, which also can perform engagement function. Besides, the actual practice for each engagement structure 122, 124, 126, 144, 146 and 148 is not limited to the disclosed structures in the above embodiment. In principle, any pair of corresponding engagement structures capable of sliding to be engaged with each other is applicable. In addition, the above installation steps are executed in reverse order for detaching the detachable cage 14 from the casing body 12, which will not be described repeatedly herein.

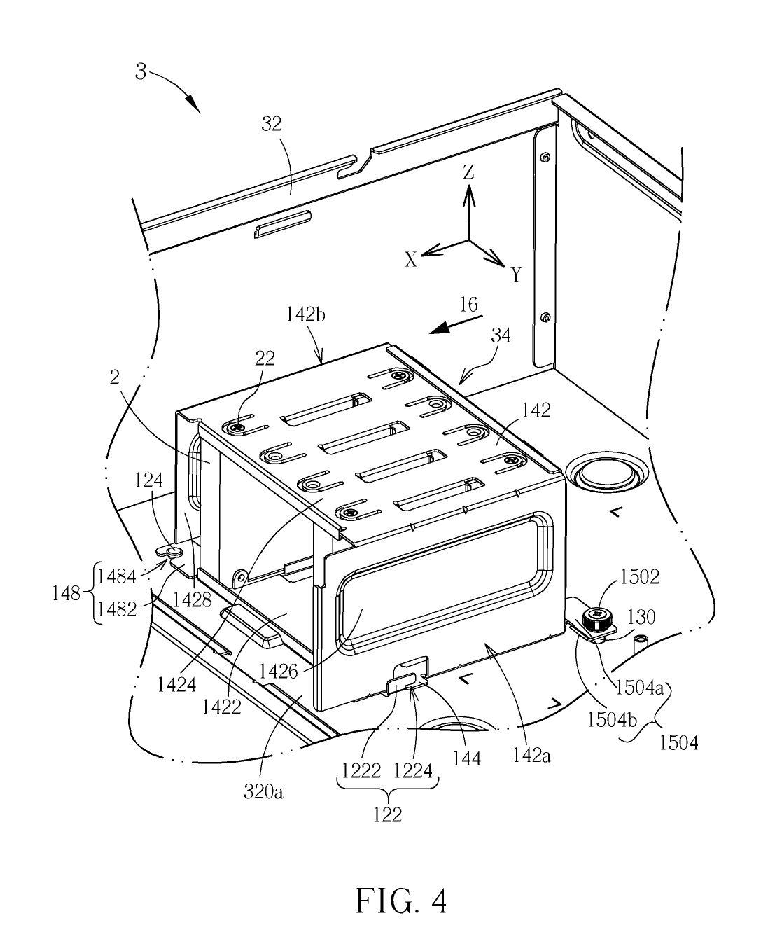

In the above embodiment, the casing body 12 is provided with the engagement structures 122, 124 and 126 on the bottom portion 120a and the sidewall 120b thereof for being engaged with the detachable cage 14, and the casing body 12 supports and constrains the cage body 142 by the bottom portion 120a and the sidewall 120b. However, the invention is not limited thereto. Please refer to FIG. 3 and FIG. 4. FIG. 4 is a schematic diagram illustrating a detachable cage 34 and a casing body 32 of an apparatus casing 3 having been engaged according to another embodiment. The apparatus casing 3 is substantially similar in structure to the apparatus casing 1, so the component labels for most components of the apparatus casing 3 continue using the component labels for the apparatus casing 1. The description of the components of the apparatus casing 1 is also applicable herein and will not be repeated. The main difference between the apparatus casing 3 and the apparatus casing 1 is that the second engagement structure 124, the fifth engagement structure 126, and the blocking structure 128 of the apparatus casing 3 are disposed on the bottom portion 320a of the casing body 32, and the third engagement structure 144, the fourth engagement structure 146, and the sixth engagement structure 148 are disposed on the first side 142a and the second side 142b close to the bottom plate 1422 of the cage body 142 correspondingly. In the embodiment, the third engagement structure 144, the fourth engagement structure 146, and the sixth engagement structure 148 (not shown in FIG. 4 because of being shadowed by the cage body 142) are formed by extending the bottom plate 1422 out the side plate 1428; however, the invention is not limited thereto. Similarly, the detachable cage 34 is capable of being engaged with the casing body 32 firmly. Furthermore, if the detachable cage 34 is required to be detached from the casing body 32, the above-mentioned description of the detachment of the detachable cage 14 from the casing body 12 is also applicable herein and will not be repeated.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A detachable cage capable of being installed in an apparatus casing in a detachable way, the apparatus casing comprising a first engagement structure, a second engagement structure, and a threaded hole, the detachable cage comprising:
a cage body capable of fixing at least one electronic device thereon, the cage body having a first side and a second side opposite to the first side;
a third engagement structure disposed on the first side of the cage body and capable of being movably engaged with the first engagement structure in a sliding direction;
a fourth engagement structure disposed on the second side of the cage body and capable of being movably engaged with the second engagement structure in the sliding direction; and
a fastening mechanism disposed on the cage body and comprising a screw part, after the third engagement structure and the fourth engagement structure are engaged with the first engagement structure and the second engagement structure respectively, the screw part being capable of being screwed into the threaded hole so as to fix the detachable cage in the apparatus casing.

2. The detachable cage of claim 1, the first engagement structure having a slide slot, wherein the third engagement structure comprises a sliding plate, and the third engagement structure is engaged with the first engagement structure by the sliding plate sliding into the slide slot and being blocked by the slide slot.

3. The detachable cage of claim 2, wherein the cage body comprises a bottom plate and a side plate, and the bottom plate extends out the side plate to form the sliding plate.

4. The detachable cage of claim 1, the second engagement structure being a guiding boss, wherein the fourth engagement structure comprises a sliding plate fixed on the cage body, the sliding plate thereon forms a slide slot, and the fourth engagement structure is engaged with the second engagement structure by the guiding boss relatively sliding in the slide slot and blocking the sliding plate.

5. The detachable cage of claim 4, wherein the cage body comprises a top plate and a side plate, and the side plate extends out the top plate to form the sliding plate.

6. The detachable cage of claim 1, the apparatus casing comprising a blocking structure, wherein the cage body comprises a side plate, and when the third engagement structure and the fourth engagement structure are engaged with the first engagement structure and the second engagement structure respectively, the blocking structure blocks an edge of the side plate.

7. The detachable cage of claim 1, wherein the fastening mechanism comprises a plate member fixed on the cage body, the plate member has a through hole, and when the third engagement structure and the fourth engagement structure are engaged with the first engagement structure and the second engagement structure respectively, the through hole is aligned with the threaded hole so that the screw part is capable of passing through the through hole to be screwed into the threaded hole.

8. The detachable cage of claim 7, wherein the screw part comprises a threaded portion and a screwing manipulation portion connected to the threaded portion, and the threaded portion is capable of passing through the through hole to be screwed into the threaded hole.

9. The detachable cage of claim 7, wherein the plate member comprises a fixed portion and a guiding portion bent to extend from the fixed portion in the sliding direction, and the through hole is formed on the fixed portion.

10. The detachable cage of claim 1, the apparatus casing comprising a fifth engagement structure, wherein the detachable cage further comprises a sixth engagement structure disposed on the second side of the cage body, and the sixth engagement structure is capable of being movably engaged with the fifth engagement structure in the sliding direction.

11. An apparatus casing, comprising:
a casing body having a threaded hole;
a first engagement structure disposed on the casing body;
a second engagement structure disposed on the casing body; and
a detachable cage, comprising:
a cage body capable of fixing at least one electronic device thereon, the cage body having a first side and a second side opposite to the first side;
a third engagement structure disposed on the first side of the cage body and capable of being movably engaged with the first engagement structure in a sliding direction;
a fourth engagement structure disposed on the second side of the cage body and capable of being movably engaged with the second engagement structure in the sliding direction; and
a fastening mechanism disposed on the cage body and comprising a screw part, after the third engagement structure and the fourth engagement structure are engaged with the first engagement structure and the second engagement structure respectively, the screw part being capable of being screwed into the threaded hole so as to fix the detachable cage on the casing body.

12. The apparatus casing of claim 11, wherein the first engagement structure comprises a fixed plate fixed on a bottom portion of the casing body, the fixed plate thereon forms a slide slot, the third engagement structure comprises a sliding plate, and the third engagement structure is engaged with the first engagement structure by the sliding plate sliding into the slide slot and being blocked by the slide slot.

13. The apparatus casing of claim 12, wherein the cage body comprises a bottom plate and a side plate, the bottom plate extends out the side plate to form the sliding plate, and the sliding plate slides on a bottom portion of the casing body during engaging of the third engagement structure with the first engagement structure.

14. The apparatus casing of claim 11, wherein the second engagement structure is a guiding boss, the fourth engagement structure comprises a sliding plate fixed on the cage body, the sliding plate thereon forms a slide slot, and the fourth engagement structure is engaged with the second engagement structure by the guiding boss relatively sliding in the slide slot and blocking the sliding plate.

15. The apparatus casing of claim 14, wherein the guiding boss is fixed on a sidewall of the casing body, the cage body comprises a top plate and a side plate, the side plate extends out the top plate to form the sliding plate, and the sliding plate slides on the sidewall of the casing body during engaging of the fourth engagement structure with the second engagement structure.

16. The apparatus casing of claim 14, wherein the guiding boss is a T-shaped guiding boss, the sliding plate slides between the T-shaped guiding boss and the casing body during engaging of the fourth engagement structure with the second engagement structure.

17. The apparatus casing of claim 11, further comprising a blocking structure disposed on the casing body, the blocking structure being formed by protruding a sidewall of the casing body, wherein the cage body comprises a side plate, and when the third engagement structure and the fourth engagement structure are engaged with the first engagement structure and the second engagement structure respectively, the blocking structure blocks an edge of the side plate.

18. The apparatus casing of claim 11, wherein the fastening mechanism comprises a plate member fixed on the cage body, the plate member has a through hole, the screw part comprises a threaded portion and a screwing manipulation portion connected to the threaded portion, and when the third engagement structure and the fourth engagement structure are engaged with the first engagement structure and the second engagement structure respectively, the through hole is aligned the threaded hole so that the threaded portion is capable of passing through the through hole to be screwed into the threaded hole.

19. The apparatus casing of claim 11, wherein the fastening mechanism comprises a plate member fixed on the cage body, the plate member comprises a fixed portion and a guiding portion bent to extend from the fixed portion in the sliding direction, the fixed portion thereon forms a through hole, the casing body comprises a protrusion boss, the threaded hole is formed on the protrusion boss, and during engaging of the third engagement structure and the fourth engagement structure with the first engagement structure and the second engagement structure respectively, the guiding portion guides the fixed portion to slide onto the protrusion boss such that the through hole is capable of being aligned with the threaded hole so that the screw part is capable of passing through the through hole to be screwed into the threaded hole for fixing the plate member on the protrusion boss.

20. The apparatus casing of claim 11, further comprising a fifth engagement structure disposed on the casing body, wherein the detachable cage further comprises a sixth engagement structure disposed on the second side of the cage body, and the sixth engagement structure is capable of being movably engaged with the fifth engagement structure in the sliding direction.
